(19) United States
(12) Patent Application Publication
(10) Pub. No.: US 2016/0307930 A1
(43) Pub. Date: Oct. 20, 2016

(54) ARRAY SUBSTRATE, MANUFACTURING METHOD THEREOF, AND DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: Zheng LIU, Beijing (CN); Jinchao BAI, Beijing (CN); Zhichao ZHANG, Beijing (CN); Xiaoxiang ZHANG, Beijing (CN); Mingxuan LIU, Beijing (CN); Tsung Chieh KUO, Beijing (CN)

(21) Appl. No.: 14/913,123

(22) PCT Filed: Aug. 20, 2015
(86) PCT No.: PCT/CN2015/087633

§ 371 Date: Feb. 19, 2016

(30) Foreign Application Priority Data
Apr. 16, 2015 (CN) 201510181256.1

(51) Int. Cl. H01L 27/12; H01L 29/66; H01L 21/3065; H01L 29/786; H01L 21/027; H01L 21/3213

(52) U.S. Cl. CPC H01L 27/1222; H01L 27/1288; H01L 21/0274; H01L 21/32139; H01L 21/3065; H01L 29/78678; H01L 29/66765

(57) ABSTRACT

The present invention provides an array substrate which is divided into a plurality of pixel units each having a first transparent electrode and a thin film transistor provided therein, the thin film transistor comprising a drain, and the drain of the thin film transistor being arranged on the first transparent electrode and electrically connected to the first transparent electrode. The present invention further provides a manufacturing method of an array substrate and a display device. Compared with the prior art, in the present invention, as the first transparent electrode is arranged below the drain, the height of a step formed on the first transparent electrode is small so that no fracture will occur on the first transparent electrode during the formation of the first transparent electrode.

### CROSS-REFERENCE TO RELATED APPLICATIONS

The present application claims the priority of application No. 201510181256.1 filed to STATE INTELLECTUAL PROPERTY OFFICE OF THE P.R.C. on Apr. 16, 2015, which is incorporated herein by reference in its entirety.

### FIELD OF THE INVENTION

The present invention relates to the field of manufacturing display devices, and in particular to an array substrate, a manufacturing method of the array substrate, and a display device including the array substrate.

### BACKGROUND OF THE INVENTION

FIG. 1 shows a partially sectional view of an array substrate in the prior art. As shown in FIG. 1, the array substrate includes a thin film transistor, a first transparent electrode 200 and a second transparent electrode 300. The first transparent electrode 200 is a pixel electrode which is lapped on and connected to a drain 520 of the thin film transistor.

In order to ensure the transparency of the array substrate, the first transparent electrode 200 usually has a small thickness (generally 300 Å to 800 Å). Since the thickness of the drain 520 of the thin film transistor is large (1500 Å to 4000 Å), the height of a step formed on the first transparent electrode 200 lapped on the drain 520 (that is, a difference in height between lower surfaces, at different levels, of the first transparent electrode 200) is large. In this case, during deposition of the thin first transparent electrode 200 on the drain 520, fractures easily occur on the first transparent electrode 200, resulting in the disconnection of circuit, thus reducing yield of production.

Therefore, how to avoid the occurrence of fractures on the first transparent electrode has become a technical problem urgently to be solved in the art.

### SUMMARY OF THE INVENTION

An object of the present invention is to provide an array substrate, a manufacturing method of the array substrate, and a display device including the array substrate. In the array substrate, fractures are not likely to occur on the first transparent electrode.

In order to achieve the object, as one aspect of the present invention, an array substrate is provided, the array substrate being divided into a plurality of pixel units each having a first transparent electrode and a thin film transistor provided therein, the thin film transistor including a drain, wherein the drain of the thin film transistor is arranged on the first transparent electrode and electrically connected to the first transparent electrode.

Optionally, the thin film transistor further includes an active layer provided below the first transparent electrode. When the active layer is made of polysilicon, the thin film transistor further includes a conductive transition layer provided between the active layer and the first transparent electrode, the conductive transition layer being conformally formed on surface(s) of the active layer, and a position of the conductive transition layer corresponding to a position of the drain of the thin film transistor; one end of the first transparent electrode is lapped on and connected to the conductive transition layer so that Ohmic contact is formed both between the first transparent electrode and the conductive transition layer and between the active layer and the conductive transition layer.

Optionally, the thin film transistor further includes a source and an additional conductive transition layer provided between the active layer and the source, the additional conductive transition layer being conformally formed on the surface(s) of the active layer, and a position of the additional conductive transition layer corresponding to a position of the source of the thin film transistor.

Optionally, each of the plurality of pixel units further includes an additional transparent electrode provided between the additional conductive transition layer and the source, the additional transparent electrode being conformally formed under a lower surface of the source.

Optionally, a thickness of the conductive transition layer is smaller than that of the drain.

Optionally, a material of the conductive transition layer is the same as that of the drain.

As another aspect of the present invention, a manufacturing method of an array substrate is provided, and the array substrate is divided into a plurality of pixel units each having a first transparent electrode and a thin film transistor provided therein, the thin film transistor including a drain, wherein the manufacturing method includes steps of: forming a pattern including the first transparent electrode; and forming a pattern including the drain on the pattern including the first transparent electrode.

Optionally, in the manufacturing method of the array substrate according to the embodiments of the present invention, the thin film transistor further includes an active layer, and the manufacturing method further includes a step of: forming, before the step of forming a pattern including the first transparent electrode, a pattern including the active layer, the pattern including the first transparent electrode being located above the pattern including the active layer.

In the manufacturing method of the array substrate according to the embodiments of the present invention, when the active layer is made of polysilicon, the manufacturing method further includes steps of: forming, after the step of forming a pattern including the active layer and before the step of forming a pattern including the first transparent electrode, a pattern including a conductive transition layer, the conductive transition layer being conformally formed on surface(s) of the active layer.

In the step of forming a pattern including the first transparent electrode, one end of the first transparent electrode is lapped on and connected to the conductive transition layer so that Ohmic contact is formed both between the first transparent electrode and the conductive transition layer and between the active layer and the conductive transition layer.

Optionally, in the manufacturing method of the array substrate according to the embodiments of the present invention, a thickness of the conductive transition layer is smaller than that of the drain.

Optionally, in the manufacturing method of the array substrate according to the embodiments of the present invention, a material of the conductive transition layer is the same as that of the drain.

Optionally, in the manufacturing method of the array substrate according to the embodiments of the present invention, the thin film transistor further includes a source, and the step of forming a pattern including the active layer, the step of forming a pattern including the conductive transition layer, the step of forming a pattern including the first transparent electrode and the step of forming a pattern including the drain specifically include steps of:

sequentially forming a pattern including a preliminary active layer and a pattern including a preliminary conductive transition layer, a profile of the preliminary active layer corresponding to a profile of the active layer, edges of the preliminary conductive transition layer being aligned to edges of the preliminary active layer, and the preliminary conductive transition layer being stacked on the preliminary active layer;

sequentially forming a transparent electrode material layer and a second metal material layer, the second metal material layer being located on the transparent electrode material layer;

forming a photoresist layer above the second metal material layer;

exposing and developing the photoresist layer to form a first mask pattern layer including a plurality of first mask patterns respectively corresponding to the pixel units, the first mask pattern including a channel hole corresponding to a spacer region between the source and the drain of the thin film transistor, each of the pixel units having one of the first mask patterns formed therein, and a shape of a region covered by the first mask pattern being consistent with a shape of upper surfaces of the source of the thin film transistor and the first transparent electrode;

removing, by etching, the material of the transparent electrode material layer and the second metal material layer except for that in a region covered by the first mask patterns;

ashing the first mask pattern layer to obtain a second mask pattern layer including a plurality of second mask patterns respectively corresponding to the pixel units, each of the pixel units having one of the second mask patterns formed therein, and a shape of a region covered by the second mask pattern being consistent with a shape of upper surfaces of the source and the drain; and

forming pattern(s) including and the source and the drain by etching, and removing the material of the preliminary conductive transition layer in the channel hole and located on the active layer by etching.

Optionally, the step of sequentially forming a pattern including the preliminary active layer and a pattern including the preliminary conductive transition layer specifically includes steps of:

sequentially forming a semiconductor material layer and a first metal material layer, the first metal material layer being located on the semiconductor material layer; and

patterning the semiconductor material layer and the first metal material layer to obtain the pattern including the preliminary active layer and the pattern including the preliminary conductive transition layer.

Optionally, the manufacturing method further includes a step of: after forming a pattern including the drain, etching a portion of the active layer corresponding to the channel hole so that a thickness of the portion of the active layer corresponding to the channel hole is smaller than that of other portions of the active layer.

As another aspect of the present invention, there is provided a display device including an array substrate, wherein the array substrate is the aforementioned array substrate provided by the present invention.

In the present invention, since the first transparent electrode is arranged below the drain, compared with the prior art, the height of a step formed on the first transparent electrode is small so that fractures are not likely to occur on the first transparent electrode during the formation of the first transparent electrode by deposition, and yield of production is improved.

### BRIEF DESCRIPTION OF THE DRAWINGS

The accompanying drawings are provided for further understanding of the present invention and constitute a part of the specification for explaining the present invention together with the following specific implementations, but not intended to limit the present invention. In the drawings:

FIG. 1 is a partially sectional view of an array substrate in the prior art;

FIG. 2 is a partially sectional view of an array substrate according to embodiments of the present invention;

FIG. 3 shows a structure after forming a gate, a preliminary active layer and a preliminary conductive transition layer on a transparent substrate by using a manufacturing method according to the embodiments of the present invention;

FIG. 4 shows a structure after forming a transparent electrode material layer and a metal material layer on the structure of FIG. 3 by using the manufacturing method according to the embodiments of the present invention;

FIG. 5 shows a structure after forming a first mask pattern on the structure of FIG. 4 by using the manufacturing method according to the embodiments of the present invention;

FIG. 6 shows a structure after removing the material of the transparent electrode material layer and the second metal material layer, except for the material in a region covered by the first mask pattern, by etching on the structure of FIG. 5 by using the manufacturing method according to the embodiments of the present invention;

FIG. 7 shows a structure after forming a second mask pattern on the structure of FIG. 6 by using the manufacturing method according to the embodiments of the present invention; and

FIG. 8 shows a structure after forming a pattern including a drain on the structure of FIG. 7 by using the manufacturing method according to the embodiments of the present invention.

### DESCRIPTION OF THE PREFERRED EMBODIMENT

The specific implementations of the present invention will be described in detail below with reference to the accompanying drawings. It should be understood that the specific implementations to be described herein are merely used for describing and explaining the present invention, but not for limiting the present invention.

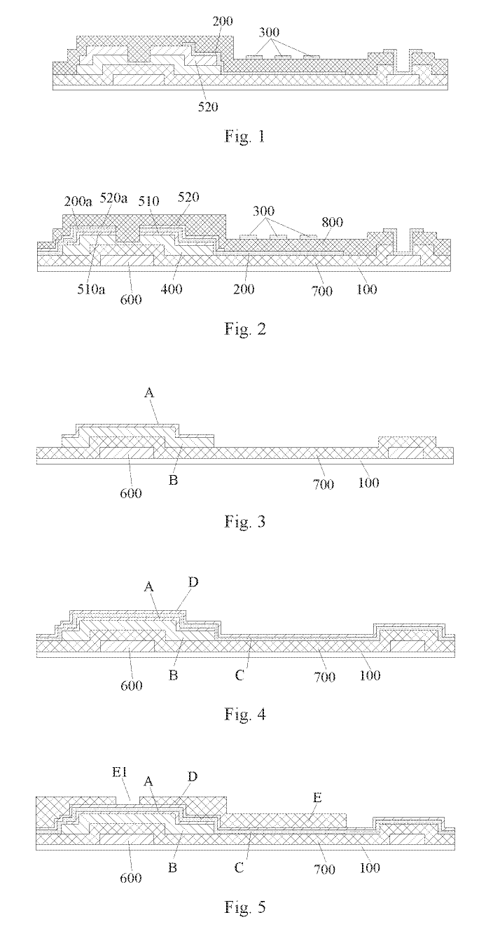

It should be understood that, in the embodiments of the present invention, the term “upper” refers to “upper” indicated in FIGS. 2-8. In the embodiments of the present invention, the term “conformally” is used for describing such a position relationship that a first layer is formed on surface(s) of a second layer, and the first layer has the same shape as that of a portion of the surface(s) of the second surface contacting the first layer without consideration of the tolerance of manufacturing process.

As shown in FIG. 2, as one aspect of the present invention, an array substrate is provided, the array substrate being divided into a plurality of pixel units each having a first transparent electrode 200 and a thin film transistor provided therein, and the thin film transistor including a drain 520 arranged on the first transparent electrode 200 and electrically connected thereto.

For those skilled in the art, it should be understood that the thin film transistor includes structures of a gate 600, a source 520a, a drain 520, an active layer 400 and the like, and as the arrangement of those structures is known to those skilled in the art, it is not described in detail in the present invention. It should be noted that, as the drain 520 of the thin film transistor is generally made of non-transparent metal material, it cannot be arranged in an opening region of the array substrate so as not to affect an aperture ratio.

Compared with the prior art, in the embodiments of the present invention, as the first transparent electrode 200 is arranged below the drain 520, the height of a step formed on the first transparent electrode 200 is small and thus no fracture will occur on the first transparent electrode 200 during the formation of the first transparent electrode 200 by deposition, thereby improving the yield of production.

In the embodiments of the present invention, each of the plurality of pixel units further has a second transparent electrode 300 provided therein. It is readily understood that the first transparent electrode 200, the second transparent electrode 300 and the thin film transistor are all arranged on a transparent substrate 100.

According to the embodiments of the present invention, one end of the first transparent electrode 200 is lapped above the active layer 400 and connected thereto. The active layer 400 starts to conduct electricity when a turn-on voltage is provided to the gate 600 of the thin film transistor, and a gray-scale signal input from the source 520a of the thin film transistor can be transmitted through the active layer 400 to the first transparent electrode 200 and the drain 520 electrically connected to the first transparent electrode 200.

In the embodiments of the present invention, there is no limitation to the specific material of the active layer, for example, the active layer 400 may be made of oxide, and may also be made of polysilicon.

When the active layer 400 is made of oxide, in order to prevent the active layer from being damaged during the formation of the first transparent electrode, it is required to form an etching barrier layer on the active layer 400 before the first transparent electrode 200 is formed; and when the active layer 400 is made of polysilicon, since no damage is caused to the active layer during the formation of the first transparent electrode, there is no need to form an etching barrier layer on the active layer.

In the embodiments of the present invention, a detailed description will be given by taking the active layer 400 made of polysilicon as an example. Generally, the transparent electrode is made of ITO (i.e., indium tin oxide), if the polysilicon directly contact with the ITO, Schottky contact is formed therebetween with large contact resistance. Optionally, in order to decrease the contact resistance between polysilicon and ITO, a conductive transition layer 510 may be optionally arranged between the active layer 400 made of polysilicon and the first transparent electrode 200 made of ITO. In the embodiments of the present invention, the material of the conductive transition layer 510 may be any material that meets the following conditions: Ohmic contact is formed both between the active layer and the conductive transition layer and between the first transparent electrode and the conductive transition layer.

Specifically, when the active layer 400 is made of polysilicon, the thin film transistor further includes a conductive transition layer 510 provided between the active layer 400 and the first transparent electrode 200, the conductive transition layer 510 being conformally formed on a surface of the active layer 400, and its position corresponding to the position of the drain 520 of the thin film transistor. One end of the first transparent electrode 200 is lapped above the conductive transition layer 510 and connected thereto.

In the embodiments of the present invention, in order to form the conductive transition layer 510, it is required to form a metal layer on the active layer 400 first and thereafter remove the metal layer corresponding to a spacer region between the source and the drain, thereby forming two portions of the metal layer separated from each other. A portion of the metal layer corresponding to the position of the drain 520 of the thin film transistor is the conductive transition layer 510, and a portion of the metal layer corresponding to the source 520a of the thin film transistor is an additional conductive transition layer 510a. In other words, the additional conductive transition layer 510a is conformally formed under a lower surface of the source 520a. The formation of the additional conductive transition layer 510a has the following advantages: during the manufacture of the array substrate, a material layer used for forming the active layer 400 and a material layer used for forming the conductive transition layer 510 may be continuously formed, and then a preliminary active layer B and a preliminary conductive transition layer A are formed by a same mask process (as shown in FIG. 3), and subsequently a transparent electrode material layer C and a metal material layer D are sequentially formed on the transparent substrate 100 having the preliminary active layer B and the preliminary conductive transition layer A formed thereon (as shown in FIG. 4), and thereafter the preliminary conductive transition layer A is made to form the additional conductive transition layer 510a and the conductive transition layer 510 by means of forming a channel hole E1.

Of course, during the formation of the conductive transition layer 510, the additional conductive transition layer 510a may not be reserved (that is, only the portion of the metal layer corresponding to the position of the drain 520 of the thin film transistor is reserved, and other portions of the metal layer are all removed by etching). In this case, it is required to perform a masking and etching process after forming the preliminary conductive transition layer A, and the conductive transition layer 510 is formed as long as the metal layer except for the portion corresponding to the position of the drain 520 of the thin film transistor is removed by etching. Compared with the aforementioned solution in which the additional conductive transition layer 510a is reserved, a masking and etching process is added. It can be seen that the reservation of the additional conductive transition layer 510a may simplify steps of manufacturing the array substrate.

Correspondingly, during the formation of the first transparent electrode 200, the transparent electrode material layer except for the portion corresponding to the position of the first transparent electrode 200 may be removed by etching, and thus only the first transparent electrode 200 located below the drain 520 is formed; alternatively, the transparent electrode material layer corresponding to a position below the source 520a may also be reserved, and thus the first transparent electrode 200 located below the drain 520 and the additional transparent electrode 200a located below the source 520a are simultaneously formed so as to omit a masking and etching process. It is to be noted that if the additional transparent electrode 200a is reserved, it is required to simultaneously reserve the additional conductive transition layer 510a to ensure a signal input by the source 520a can be transmitted to the active layer 400. Optionally, both the additional conductive transition layer 510a and the additional transparent electrode 200a are reserved in the thin film transistor, and thus the steps of manufacturing the array substrate may be simplified.

Optionally, in order to further ensure that no fracture will occur on the first transparent electrode 200, the thickness of the conductive transition layer 510 is optionally smaller than the thickness of the drain 520. As the thickness of the conductive transition layer 510 is small, the step height (i.e., the height of a step) of the first transparent electrode 200 during the formation of the first transparent electrode 200 may be reduced.

Optionally, in order to simplify the manufacturing method of the array substrate, the available material of the conductive transition layer 510 is the same as the material of the drain 520. For example, when the drain 520 is made of a metal of aluminum, the conductive transition layer 510 is also made of the metal of aluminum.

Of course, the material of the conductive transition layer 510 may be different from the material of the drain 520. For example, when the conductive transition layer 510 is made of the metal of aluminum, the drain may include a triple-layer metal structure including MoAlMo (molybdenum, aluminum, molybdenum).

As shown in FIG. 2, the array substrate according to the embodiments of the present invention may further include a second transparent electrode 300, a gate insulating layer 700 located between a gate layer (including a gate line, a common electrode line, a gate and the like) and the active layer, and a passivation layer 800 located above the active layer. The second transparent electrode 300 is formed on the passivation layer 800, and the second transparent electrode 300 may be a comb electrode for electrically connecting to the common electrode line in the gate layer by a via. In this case, correspondingly, the first transparent electrode 200 is a block electrode.

Referring to FIGS. 3-8, as another aspect of the present invention, a manufacturing method of the array substrate is provided, wherein the array substrate is divided into a plurality of pixel units each having a first transparent electrode and a thin film transistor provided therein, and the manufacturing method includes steps of: forming a pattern including a first transparent electrode; and forming a pattern including a drain on the pattern including the first transparent electrode.

In the embodiments of the present invention, since the first transparent electrode is arranged below the drain, compared with the prior art, the height of a step on the first transparent electrode is small so that fractures are not likely to occur on the first transparent electrode during the formation of the first transparent electrode.

In the embodiments of the present invention, each of the plurality of the pixel units further has a second transparent electrode provided therein, and the thin film transistor includes an active layer, a gate, a source, the drain, and other structures.

The manufacturing method according to the embodiments of the present invention further includes a step of: forming, before the step of forming the pattern including the first transparent electrode, a pattern including an active layer. In this case, the pattern including the first transparent electrode is formed above the pattern including the active layer, that is, the pattern including the first transparent electrode is located above the pattern including the active layer.

In the above steps, the pattern including the active layer includes a plurality of active layers respectively corresponding to the thin film transistors of the pixel units. The patterns including the drains include the drains of the thin film transistors and also include the sources of the thin film transistors, a plurality of data lines and the like.

As described above, in the embodiments of the present invention, the material for forming the active layer is not limited. For example, the active layer may be made of oxide, and may also be made of polysilicon.

In the manufacturing method according to the embodiments of the present invention, when the active layer is made of oxide, in order to prevent damage to the active layer during the formation of the first transparent electrode, it is required to form an etching barrier layer on the active layer before the first transparent electrode is formed; and when the active layer is made of polysilicon, since no damage is caused to the active layer during the formation of the first transparent electrode, there is no need to form an etching barrier layer on the active layer.

In the manufacturing method according to the embodiments of the present invention, when the active layer is made of polysilicon, since the transparent electrode is usually made of ITO, if the polysilicon directly contacts with the ITO, Schottky contact is formed therebetween with large contact resistance. In order to decrease the contact resistance between the polysilicon and the ITO, optionally, the manufacturing method further includes steps of: forming, after the step of forming a pattern including the active layer and before the step of forming a pattern including the first transparent electrode, a pattern including a conductive transition layer, the conductive transition layer being conformally formed on a surface of the active layer and its position corresponding to the position of the drain. In this case, one end of the first transparent electrode is lapped on and connected to the conductive transition layer so that Ohmic contact is formed both between the first transparent electrode and the conductive transition layer and between the active layer and the conductive transition layer.

In the manufacturing method according to the embodiments of the present invention, the material of the conductive transition layer may be any material that can meet the following requirements: Ohmic contact is formed both between the first transparent electrode and the conductive transition layer and between the active layer and the conductive transition layer.

Optionally, in the manufacturing method according to the embodiments of the present invention, the thickness of the conductive transition layer is smaller than the thickness of the drain, to reduce the height of the step on the first transparent electrode.

Optionally, the conductive transition layer has the same material as that of the source and the drain so as to simplify the manufacturing method of the array substrate.

In the present invention, the specific manner of forming the pattern layers is not limited. Usually, the pattern layers may be formed by a photolithographic patterning process.

Optionally, in order to simplify the manufacturing method of the array substrate, the step of forming the pattern including the active layer, the step of forming the pattern including the conductive transition layer, the step of forming the pattern including the first transparent electrode and the step of forming the pattern including the drain specifically include:

sequentially forming a pattern including a preliminary active layer B and a pattern including a preliminary conductive transition layer A, a profile of the preliminary active layer B corresponding to a profile of the active layer, edges of the preliminary conductive transition layer A being aligned to edges of the preliminary active layer B, and the preliminary conductive transition layer A being stacked on the preliminary active layer B (as shown in FIG. 3), wherein the pattern including the preliminary active layer B includes a plurality of preliminary active layers B respectively corresponding to the thin film transistors of the pixel units, and the pattern including the preliminary conductive transition layer A includes a plurality of preliminary conductive transition layers A respectively corresponding to the thin film transistors of the pixel units;

sequentially forming a transparent electrode material layer C and a second metal material layer D (as shown in FIG. 4), the second metal material layer D being located on the transparent electrode material layer C;

forming a photoresist layer on the second metal material layer D;

exposing and developing the photoresist layer to form a first mask pattern layer including a plurality of first mask patterns E respectively corresponding to the pixel units, in other words, each of the pixel units having one of the first mask patterns E formed therein (as shown in FIG. 5), the first mask pattern E including a channel hole E1 corresponding to a spacer region between the source and the drain of the thin film transistor, and a shape of a region covered by the first mask patterns E being consistent with a shape of upper surfaces of the source of the thin film transistor and the first transparent electrode;

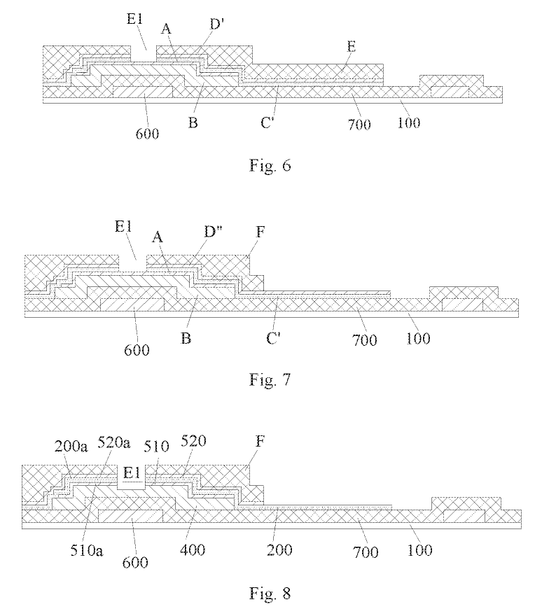

removing, by etching, the material of the transparent electrode material layer C and the second metal material layer D except for the material in a region covered by the first mask patterns E (as shown in FIG. 6);

ashing the first mask pattern layer to obtain a second mask pattern layer including a plurality of second mask patterns F respectively corresponding to the pixel units, in other words, each of the pixel units having one of the second mask patterns F formed therein (as shown in FIG. 7), and a shape of a region covered by the second mask patterns F being consistent with a shape of upper surfaces of the source and the drain of the thin film transistor; and

forming a pattern including the drain by etching, and removing the preliminary conductive transition layer A in the channel hole E1 and located on the active layer 400 by etching (as shown in FIG. 8). By this etching, it is possible to prevent the conducting material from remaining on the surface of the active layer 400, so that it can ensure the normal turn-on and normal turn-off of the thin film transistor and facilitate improvement of the yield of display panels. During etching, the second mask patterns F may prevent the material in a region covered by the second mask patterns F from being etched, and the metal material layer which is not etched forms the source and the drain of the thin film transistor.

It should be understood that “a shape of upper surfaces of the source of the thin film transistor and the first transparent electrode” as described herein refers to the shape of a combination formed by the upper surface of the source of the thin film transistor and the upper surface of the first transparent electrode, and “a shape of upper surfaces of the source and the drain” refers to the shape of a combination formed by the upper surface of the source and the upper surface of the drain.

As described above, before forming the source and the drain by an etching process, the preliminary conductive transition layer A being on the active layer and at a position corresponding to the source is not removed by etching. This may reduce a masking and etching process, thus simplifying the manufacturing method of the array substrate and reducing the production cost.

Optionally, in the manufacturing method according to the embodiments of the present invention, the thickness of the active layer 400 at a position corresponding to the channel hole E1 is smaller than the thickness of the active layer 400 at other positions, so as to ensure that there is no residual conducting material on the active layer. Therefore, the manufacturing method further includes a step of: after forming the pattern including the drain, etching a portion of the active layer corresponding to the channel hole E1 so that the thickness of the portion of the active layer corresponding to the channel hole is smaller than the thickness of the other portions of the active layer.

In the manufacturing method according to the embodiments of the present invention, all the above steps may be done by dry etching.

In the manufacturing method according to the embodiments of the present invention, the second metal material layer D may include a plurality of metal sub-layers stacked therein, and two adjacent metal sub-layers may have different compositions. For example, the second metal layer may be an AlMoAl (aluminum, molybdenum, aluminum) triple-layer metal structure.

In the manufacturing method according to the embodiments of the present invention, the step of sequentially forming a pattern including the preliminary active layer B and a pattern including the preliminary conductive transition layer A may specifically include steps of:

sequentially forming a semiconductor material layer and a first metal material layer, the first metal material layer being located on the semiconductor material layer; and

patterning the semiconductor material layer and the first metal material layer to obtain the pattern including the preliminary active layer B and the pattern including the preliminary conductive transition layer A (as shown in FIG. 3).

Optionally, in the manufacturing method according to the embodiments of the present invention, composition(s) of the first metal material layer may be the same as that(those) of the second metal material layer D so as to simplify the manufacturing method of the array substrate. Of course, composition(s) of the first metal material layer may be different from that(those) of the second metal material layer.

It may be easily understood by those skilled in the art that the manufacturing method according to the embodiments of the present invention may further include the steps of: before forming the pattern including the active layer, sequentially forming a pattern including a gate 600 and the gate insulating layer, the gate insulating layer being located on the pattern including the gate, wherein the active layer is formed on the gate insulating layer above the gate. The pattern including the gate includes gates of the thin film transistors, and further includes gate line(s) and common electrode line(s).

It may be easily understood by those skilled in the art that the manufacturing method according to the embodiments of the present invention may further include the steps of: after forming the pattern including the drain, sequentially forming a passivation layer and a pattern including a second transparent electrode, the pattern including the second transparent electrode being located on the passivation layer, wherein the passivation layer covers the pattern including the drain, and the second transparent electrode is a comb electrode which is connected to the common electrode line by a via.

As another aspect of the present invention, there is provided a display device including an array substrate, wherein the array substrate is the aforementioned array substrate provided by the present invention.

It may be easily understood that the display device may be a liquid crystal display device, and the display device further includes an opposite substrate arranged with and aligned to the array substrate to form a cell. A color film layer may be arranged on the opposite substrate to realize the color display.

The display device may be a display, a notebook computer, a navigator, a mobile phone, a tablet computer or the like.

It may be understood that the forgoing implementations are merely exemplary implementations adopted for illustrating the principle of the present invention, but the present invention is not limited thereto. Various modifications and improvements may be made by a person having ordinary skill in the art without departing from the spirit and essence of the present invention, and these modifications and improvements should also be regarded as falling into the protection scope of the present invention.

1. An array substrate, the array substrate being divided into a plurality of pixel units each having a first transparent electrode and a thin film transistor provided therein, the thin film transistor comprising a drain, wherein the drain of the thin film transistor is arranged on the first transparent electrode and electrically connected to the first transparent electrode.

2. The array substrate according to claim 1, wherein the thin film transistor further comprises an active layer provided below the first transparent electrode.

3. The array substrate according to claim 2, wherein the active layer is made of polysilicon, and the thin film transistor further comprises a conductive transition layer provided between the active layer and the first transparent electrode, the conductive transition layer being conformally formed on a surface of the active layer, and a position of the conductive transition layer corresponding to a position of the drain of the thin film transistor; one end of the first transparent electrode is lapped above and connected to the conductive transition layer such that Ohmic contact is formed both between the first transparent electrode and the conductive transition layer and between the active layer and the conductive transition layer.

4. The array substrate according to claim 3, wherein the thin film transistor further comprises a source and an additional conductive transition layer provided between the active layer and the source, the additional conductive transition layer being conformally formed on the surface of the active layer, and a position of the additional conductive transition layer corresponding to a position of the source of the thin film transistor.

5. The array substrate according to claim 4, wherein each of the plurality of pixel units further comprises an additional transparent electrode provided between the additional conductive transition layer and the source, the additional transparent electrode being conformally formed under a lower surface of the source.

6. The array substrate according to claim 3, wherein a thickness of the conductive transition layer is smaller than that of the drain.

7. The array substrate according to claim 3, wherein a material of the conductive transition layer is the same as that of the drain.

8. A manufacturing method of an array substrate, wherein the array substrate is divided into a plurality of pixel units each having a first transparent electrode and a thin film transistor provided therein, the thin film transistor comprising a drain, the manufacturing method comprising steps of:
forming a pattern comprising the first transparent electrode; and
forming a pattern comprising the drain on the pattern comprising the first transparent electrode.

9. The manufacturing method according to claim 8, wherein the thin film transistor further comprises an active layer, the manufacturing method further comprising a step of:
forming, before the step of forming a pattern comprising the first transparent electrode, a pattern comprising the active layer, the pattern comprising the first transparent electrode being located above the pattern comprising the active layer.

10. The manufacturing method according to claim 9, wherein the active layer is made of polysilicon, the manufacturing method further comprising steps of:
forming, after the step of forming a pattern comprising the active layer and before the step of forming a pattern comprising the first transparent electrode, a pattern comprising a conductive transition layer, the conductive transition layer being conformally formed on a surface of the active layer, wherein,
in the step of forming a pattern comprising the first transparent electrode, one end of the first transparent electrode is lapped on and connected to the conductive transition layer such that Ohmic contact is formed both between the first transparent electrode and the conductive transition layer and between the active layer and the conductive transition layer.

11. The manufacturing method according to claim 10, wherein a thickness of the conductive transition layer is smaller than that of the drain.

12. The manufacturing method according to claim 10, wherein a material of the conductive transition layer is the same as that of the drain.

13. The manufacturing method according to claim 10, wherein the thin film transistor further comprises a source, and the step of forming a pattern comprising the active layer, the step of forming a pattern comprising a conductive transition layer, the step of forming a pattern comprising the first transparent electrode and the step of forming a pattern comprising the drain specifically comprise steps of:
sequentially forming a pattern comprising a preliminary active layer and a pattern comprising a preliminary conductive transition layer, a profile of the preliminary active layer corresponding to a profile of the active layer, edges of the preliminary conductive transition layer being aligned to edges of the preliminary active layer, and the preliminary conductive transition layer being stacked on the preliminary active layer;
sequentially forming a transparent electrode material layer and a second metal material layer, the second metal material layer being located on the transparent electrode material layer;
forming a photoresist layer above the second metal material layer;
exposing and developing the photoresist layer to form a first mask pattern layer comprising a plurality of first mask patterns respectively corresponding to the pixel units, the first mask pattern comprising a channel hole corresponding to a spacer region between the source and the drain of the thin film transistor, each of the pixel units having one of the first mask patterns formed therein, and a shape of a region covered by the first mask pattern being consistent with a shape of upper surfaces of the source of the thin film transistor and the first transparent electrode;
removing the material of the transparent electrode material layer and the second metal material layer, except for that in a region covered by the first mask patterns, by etching;
ashing the first mask pattern layer to obtain a second mask pattern layer comprising a plurality of second mask patterns respectively corresponding to the pixel units, each of the pixel units having one of the second mask patterns formed therein, and a shape of a region covered by the second mask pattern being consistent with a shape of upper surfaces of the source and the drain; and
forming a pattern comprising the drain by etching, and removing a portion of preliminary conductive transition layer in the channel hole and located on the active layer by etching.

14. The manufacturing method according to claim 13, wherein the step of sequentially forming a pattern comprising a preliminary active layer and a pattern comprising a preliminary conductive transition layer specifically comprises steps of:
sequentially forming a semiconductor material layer and a first metal material layer, the first metal material layer being located on the semiconductor material layer; and
patterning the semiconductor material layer and the first metal material layer to obtain the pattern comprising the preliminary active layer and the pattern comprising the preliminary conductive transition layer.

15. The manufacturing method according to claim 13, further comprising a step of:
after forming a pattern comprising the drain, etching a portion of the active layer corresponding to the channel hole so that a thickness of the portion of the active layer corresponding to the channel hole is smaller than that of other portions of the active layer.

16. The manufacturing method according to claim 15, wherein the portion of the active layer corresponding to the channel hole is etched by dry etching.

17. The method according to claim 13, wherein the second metal layer is formed by stacking a plurality of layers of metal material.

18. A display device comprising an array substrate, wherein the array substrate is the array substrate according to claim 1.

19. A display device comprising an array substrate, wherein the array substrate is the array substrate according to claim 3.

20. A display device comprising an array substrate, wherein the array substrate is the array substrate according to claim 4.
